(19) United States
(12) Patent Application Publication
(10) Pub. No.: US 2026/0090426 A1
(43) Pub. Date: Mar. 26, 2026

(54) SEMICONDUCTOR CORE LAYER INCLUDING GLASS SHEET HAVING EDGE PROTECTION STRUCTURE AND METHOD OF MAKING SAME

(71) Applicant: Intel Corporation, Santa Clara, CA (US)

(72) Inventors: Mahdi Mohammadighaleni, Phoenix, AZ (US); Shayan Kaviani, Phoenix, AZ (US); Joshua J. Stacey, Chandler, AZ (US); Thomas S. Heaton, Gilbert, AZ (US); Ehsan Zamani, Phoenix, AZ (US); Elham Tavakoli, Phoenix, AZ (US); Srinivas Venkata Ramanuja Pietambaram, Chandler, AZ (US); Gang Duan, Chandler, AZ (US); Seyyed Yahya Mousavi, Chandler, AZ (US)

(73) Assignee: Intel Corporation, Santa Clara, CA (US)

(21) Appl. No.: 18/895,028

(22) Filed: Sep. 24, 2024

(51) Int. Cl. H01L 23/13; H01L 21/48; H01L 23/15; H01L 23/538

(52) U.S. Cl. CPC H10W 70/68; H10W 70/05; H10W 70/611; H10W 70/685; H10W 70/692

(57) ABSTRACT

A core layer of a package substrate includes a sheet including glass; structures defining electrically conductive pathways within the sheet; and a saw street structure (SSS) at one or more lateral edges of the sheet, the SSS one or more oblong bodies in respective cavities defined in one or more lateral edges of the sheet, individual ones of the one or more oblong bodies extending in a direction along a thickness of the sheet, having a lateral edge surface facing away from the sheet, and comprising a material (SSS material) including at least one of a polymer or a metal. The core layer further includes a plurality of build-up layers on at least one of a top surface or a bottom surface of the core layer, the plurality of build-up layers electrically coupled to the electrically conductive pathways of the core layer.

### BACKGROUND

A package substrate may be used in an electronic device to provide electrical and mechanical support to integrated circuit components coupled thereto. A package substrate may host a network of conductive traces that connect various components on the surface of the package substrate. The package substrate may also feature conductive pathways (e.g., vias) that traverse the layers of the substrate, enabling connections between different layers of the package substrate. In some instances, a package substrate may provide electrical connection between one or more integrated circuit components and various circuits of a printed circuit board upon which the package substrate is mounted. In some instances, a package substrate may include a core layer with one or more sheets including glass.

### BRIEF DESCRIPTION OF THE DRAWINGS

Some embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1A is a cross sectional view of a microelectronic assembly including a core layer according to an embodiment.

FIG. 1B is a perspective view of a sheet including glass from the microelectronic assembly of FIG. 1A according to an embodiment.

FIGS. 2A-C illustrate an example of a glass panel that may be used to form a core layer according to some embodiments.

FIGS. 3A-3G show respective stages of fabrication of a core layer from glass panel structures according to some embodiments.

FIG. 4 is a flow chart of a process according to some embodiments.

FIG. 5 is a cross-sectional side view of an integrated circuit device assembly that may include a core layer in accordance with any of the embodiments disclosed herein.

FIG. 6 is a block diagram of an example electrical device that may include a core layer in accordance with any of the embodiments disclosed herein.

### DETAILED DESCRIPTION

In some implementations, a package substrate may comprise a glass core sandwiched between buildup layers. Recently, glass cores have been explored as alternatives to organic resin-based cores (e.g., cores based on Ajinomoto Buildup Film (ABF)). For a variety of reasons, glass is expected to improve the mechanical and electrical performance of semiconductor substrate packages over other core materials. For example, glass is considered more rigid than organic resin-based materials and has several advantages such as excellent thermal properties, a low coefficient of thermal expansion (CTE), high electrical insulation, chemical resistance, optical transparency, and compatibility with advanced semiconductor properties. In some instances, glass cores may facilitate transmission of high frequency signals within the package. As another example, glass cores also allow improved coplanarity over cores made from organic materials.

Implementing a glass core can introduce a variety of technical challenges and reliability issues. A major challenge for widespread adoption of glass cores is the susceptibility of the glass to damage due to mechanical and/or thermal stresses. For example, glass core substrates with a high number of buildup layers have a high risk of glass splitting in the core due to internal residual buildup stress as well as CTE mismatch between the core and buildup layers. During a depaneling or singulation step, any defects introduced during any of the upstream process steps in the glass core material coupled w/ high CTE mismatch between the glass core and buildup material can easily lead to glass separation. The risk of glass splitting is especially high for thicker core substrates.

As another example, contact with the glass by various toolsets in the line can lead to minor defects along the glass edge, eventually leading to breaks in the glass. Upgrading equipment and overhauling the process flow in order to alleviate these risks to improve yield can be costly.

Crack formation and propagation in glass compromises the structural integrity of glass, making microelectronic assemblies with glass cores particularly prone to failure over time. Embodiments of the present disclosure relate to various techniques, as well as to related devices and methods, for alleviating (e.g., mitigating or reducing) crack formation and propagation in glass panels used to form glass cores or other glass structures used in integrated circuit packages.

A hybrid reconstitution process may include providing a protective edge (referred to herein as a frame) around the glass panel while simultaneously encapsulating the glass panel in a standard use dielectric material. This allows fragile glass core panels to be used within standard organic panel line toolsets. However, various challenges may be associated with manufacturing of the organic frame and placement of the glass within the frame. For example, manufacturing the organic frame may increase the cost or difficulty of the manufacturing process and require an additional tool. Furthermore, accurate placement of the glass within the frame may also be difficult and require additional tools or materials.

Moreover, the hybrid reconstitution process may leave a fragile gap between the glass panel and the frame (e.g., which may comprise an organic material, such as copper clad laminate) around the glass panel, which needs to be reinforced to survive further processing. A buildup layer material, such as Ajinomoto buildup film (ABF) may be placed in the gap. However, buildup layer materials such as ABF may be relatively brittle and may be subject to cracking during subsequent process steps. Accordingly, a reinforcement material may be placed in the footprint of the gap (e.g., over the gap and/or below the gap). For example, a reinforcement strip comprising glass cloth prepreg (GCP) or resin coated copper (RCC) may be used to provide reinforcement across the gap.

Various embodiments of the present disclosure provide improved protection of glass panels during a manufacturing process through improved reinforcement materials at lateral edges of units of a glass panel in the region of saw streets of the glass panel.

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims. In the following description, various aspects of the illustrative implementations will be described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials, and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings that form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

The technologies described herein may be implemented in one or more electronic devices. Non-limiting examples of electronic devices that may utilize the technologies described herein include any kind of mobile device and/or stationary device, such as microelectromechanical systems (MEMS) based electrical systems, gyroscopes, advanced driving assistance systems (ADAS), 5G communication systems, cameras, cell phones, computer terminals, desktop computers, electronic readers, facsimile machines, kiosks, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. Such devices may be portable or stationary. In some embodiments, the technologies described herein may be employed in a desktop computer, laptop computer, smart phone, tablet computer, netbook computer, notebook computer, personal digital assistant, server, combinations thereof, and the like. More generally, the technologies described herein may be employed in any of a variety of electronic devices, including semiconductor packages with passive heat spreaders, interface layers, TIMs, top dies, side dies, substrates, and package substrates.

As used herein the terms “top,” “bottom,” “upper,” “lower,” “lowermost,” and “uppermost” when used in relationship to one or more elements are intended to convey a relative rather than absolute physical configuration. Thus, an element described as an “uppermost element” or a “top element” in a device may instead form the “lowermost element” or “bottom element” in the device when the device is inverted. Similarly, an element described as the “lowermost element” or “bottom element” in the device may instead form the “uppermost element” or “top element” in the device when the device is inverted.

As used herein, reference to a “die” is meant to broadly refer to a die, a chiplet, a chip complex, a chiplet complex, or any other integrated circuit structure including circuitry therein supported on a substrate. While the terms die, chip, and chiplet may be used interchangeably, the term chiplet is sometimes used to refer to an integrated circuit die that implements a subset of the functionality of a larger integrated circuit component, the larger integrated circuit component formed using one or more chiplets connected by inter-die interconnects (e.g., interposers, bridges, local interconnect components, local silicon interconnects). The use of chiplets in integrated circuit components has become attractive as feature sizes have reduced and the demand for high-performance larger integrated circuit components has increased. The approach of assembling multiple known-good dies (chiplets) to form a larger integrated circuit component results in improved manufacturing efficiencies as the overall yield of an integrated circuit component assembled from multiple small chiplets is better than that of an integrated circuit component in which the functionality of the chiplets is implemented on a single large integrated circuit die. Any integrated circuit die, chip, or chiplet can implement any portion of the functionality of any processor unit described or referenced herein.

As used herein, the term “electronic component” can refer to an active electronic circuit/active electronic component (e.g., processing unit, die, chiplet, memory, High Bandwidth Memory (HBM), storage device, FET, etc.) or a passive electronic circuit/passive electronic component (e.g., resistor, inductor, capacitor, etc.).

As used herein, the term “active” or “electrically active” when referring to a region of a semiconductor structure or microelectronic structure refers to a region of such structure that is configured to conduct electricity. “Active” in the context of a semiconductor/microelectronic structure, or in the context of an electronic component (e.g., an “active” component versus a “passive” component), is not meant to necessarily be construed as referring to a device in operation.

As used herein, the term “the material” of component A may refer to one or more constituent materials of component A. For example, where component A includes 3 sublayers or subregions made of three respective materials X, Y and Z, the disclosure herein may refer to “the material of component A” to refer to materials X, Y and Z that make up component A.

As used herein, the term “integrated circuit component” can refer to a combination of an electronic component and a semiconducting material, the electronic component on the semiconductor material, where the assembly is configured to perform a function. An integrated circuit (IC) component can comprise one or more of any electronic components, such as any electronic components described or referenced herein, or any other computing system component, such as a processor unit (e.g., system-on-a-chip (SoC), processor core, graphics processor unit (GPU), accelerator, chipset processor), I/O controller, memory, or network interface controller, and can comprise one or more additional active or passive devices such as capacitors, decoupling capacitors, resistors, inductors, fuses, diodes, transformers, sensors, electrostatic discharge (ESD) devices, and memory devices.

A non-limiting example of an unpackaged integrated circuit component includes a single monolithic integrated circuit die (shortened herein to “die”); the die may include solder bumps attached to contacts on the die, or contacts on the die can allow the die to be hybrid bonded to other contacts on other devices, such as on a package substrate. When present on the die, the solder bumps or other conductive contacts can enable the die to be directly attached to a printed circuit board (PCB) or other substrates.

An existing example of a packaged integrated circuit component comprises one or more integrated circuit dies mounted on a package substrate with the integrated circuit dies and package substrate encapsulated in a casing material, such as a metal, plastic, glass, or ceramic. Often the casing includes an integrated heat spreader (IHS); the packaged integrated circuit component often has bumps, leads, or pins attached to the package substrate (either directly or by wires attaching the bumps, leads, or pins to the package substrate) for attaching the packaged integrated circuit component to a printed circuit board (or motherboard or base board) or another component.

As used herein, “pitch” may be measured center-to-center between two elements (e.g., from a center of a through-via to a center of an adjacent through-via).

As used herein, “contacts” may refer to electrically conductive structures of or on a first microelectronic component (e.g., an electronic component, a substrate, a panel layer, etc.) that may be electrically coupled to contacts of a second microelectronic component. Contacts may include, for example, solder balls, pads, or pins.

“Electrically conductive structures” as used herein may include an electrically conductive material such as a metal (e.g., copper, aluminum, nickel, cobalt, iron, tin, gold, silver, or combinations thereof). Examples of electrically conductive structures may include traces, which extend horizontally, and vias, which extend vertically.

As used herein, the term “electrically conductive pathway” refers to electrically conductive structures such as traces, vias, contacts, metallization layer coatings, metallization layers, contacts (e.g., solder balls, pads, pins, pillars, etc.).

By “A is embedded in B,” what is meant herein is that B at least partially covers side surfaces of A, and at most covers all surfaces of A.

The following detailed description is not intended to limit the application and use of the disclosed technologies. It may be evident that the novel embodiments can be practiced without every detail described herein. For the sake of brevity, well-known structures and devices may be shown in block diagram form to facilitate a description thereof.

For convenience, a phrase referring to element “X,” where X is a reference numeral, may be used to refer to any one of elements XA or XB if such elements have been disclosed.

A glass sheet of a core layer, a core layer, a package substrate including the core layer, a microelectronic assembly, and related devices and methods, are disclosed herein.

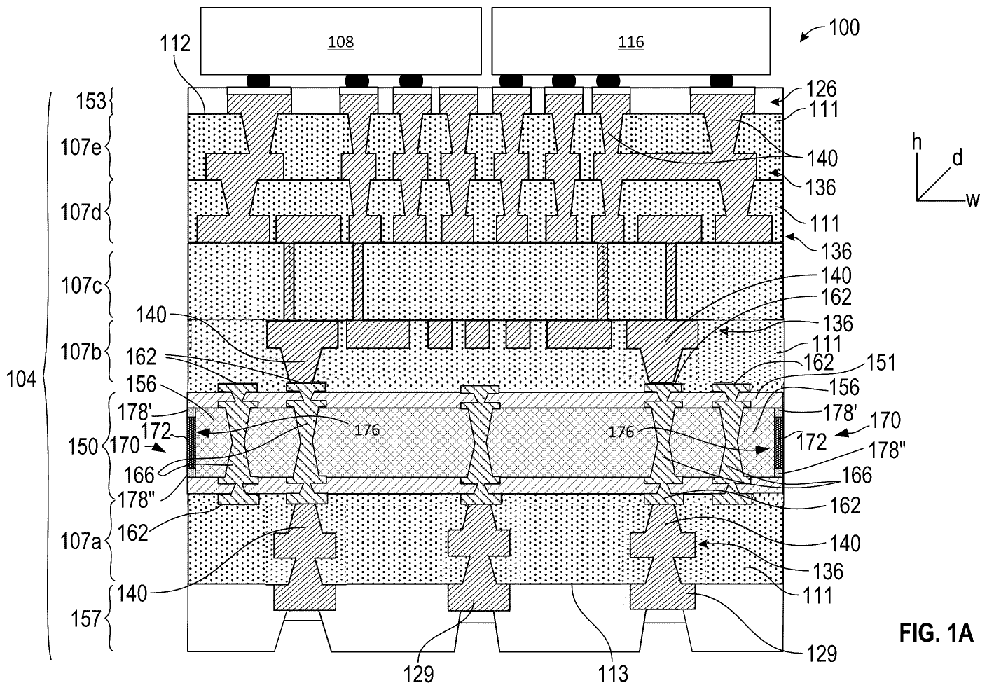

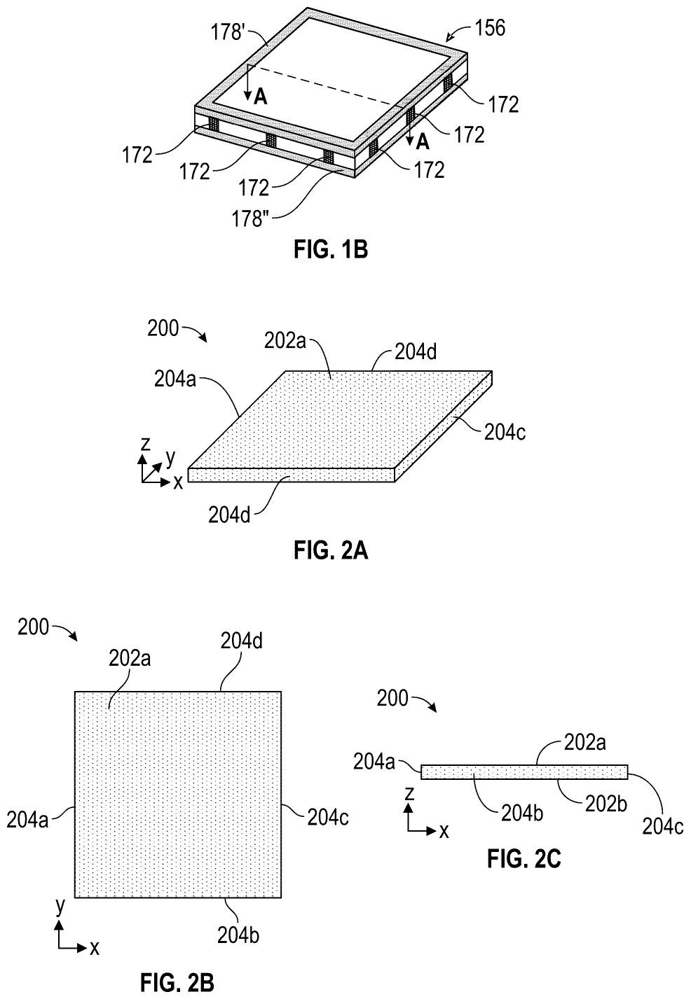

FIG. 1A is a cross-sectional view of an example microelectronic assembly 100 according to a first embodiment. Package substrate 104, includes redistribution layers (RDLs) or build-up layers 107a-107e, and a core layer 150. The package substrate 104 corresponds to a microelectronic structure.

Persons with skill in the art may appreciate that the distinctions in the various build-up layers attributed to the build-up layers 107a-107e in this discussion have been introduced for illustrative purposes; in a cross-sectional image of the package substrate 104, such as by a transmission electron microscope (TEM), the layers 107a-107e may be indistinguishable, and different from the ones shown in the figure, and there may be more or less of the build-up layers than the ones shown.

Electrically conductive structures provide signal communication for die 108 and for die 116, and throughout the microelectronic assembly 100, through and within core layer 150, and, as seen at build-up layer 107a, conductive contacts 129 that may couple the microelectronic assembly to a motherboard or other circuit component. Electrically conductive structures of the package substrate 104 may include traces 136 (including for example contacts), and vias 140. Traces 136 may be arranged to route electrical signals in a horizontal direction, and vias 140 may be arranged to route electrical signals in a vertical direction. The electrically conductive structures may include an electrically conductive material such as a metal (e.g., copper, aluminum, nickel, cobalt, iron, tin, gold, silver, or combinations thereof). A passivation layer 153 in the form of solder resist or other dielectric material on the upper substrate surface 112 of package substrate 104 may be patterned with a respective pinouts (physical arrangement of conductive contacts 126 at a respective pitch) for individual dies such as dies 108 and 116. A passivation layer 157 in the form of solder resist or other dielectric material on the lower substrate surface 113 of package substrate 104 may also be patterned with a respective pinouts (physical arrangement of conductive contacts 129 at a respective pitch) for electrical coupling of the microelectronic assembly 100 to another component, such as a motherboard. The buildup layers may further include a non-conductive material 111 within which the traces 136 and vias 140 may be embedded.

The build-up layers 107a-107e, although shown in FIG. 1A (and in some subsequent figures herein) as a handful of layers, can include any number of build-up layers or sublayers. For example, in server applications, there can be up to 10 build-up layers. In various embodiments, a build-up layer comprises a dielectric material and may include a suitable nitride or oxide, such as silicon dioxide (SiO₂), carbon-doped silicon dioxide (C-doped SiO₂, also known as CDO or organosilicate glass, which is a material that comprises silicon, oxygen, and carbon), fluorine-doped silicon dioxide (F-doped SiO₂, also known as fluorosilicate glass, which is a material that comprises fluorine, silicon, and oxygen), hydrogen-doped silicon dioxide (H-doped SiO₂, which is a material that comprises silicon, oxygen, and hydrogen). In some embodiments, a build-up layer comprises a photo-imageable dielectric (PID). In some embodiments, a build-up layer may comprise an Ajinomoto Build-Up film (often referred to as ABF), which is a material that comprises an organic resin matrix with different types of fillers (for example, silica fillers of different sizes, or hollow fillers of different sizes) to control the coefficient of thermal expansion (CTE) and/or electrical properties of the build-up layers (e.g., the dielectric constant (Dk), and/or dissipation factor (insertion loss) (Df)).

Package substrate 104 as shown corresponds to a microelectronic structure in the form of a printed circuit board that may include a core layer 150. The core layer 150 may correspond to a core substrate, and may be disposed in a region of the package substrate 104 between top and bottom build-up layers of the latter.

The core layer 150 may include a sheet including glass (hereinafter “glass sheet”) 156, the glass sheet 156 defining holes therein, such as through-holes as shown to receive vias therein, such as through-vias 166. According to some embodiments, the core layer 150 may include one or more glass sheets similar to glass sheet 156 of FIG. 1A.

The glass material of the glass sheet 156 within core layer 150 may include silicon, and, in addition, optionally at least one of oxygen or boron. For example, the glass material may include silicon, oxide, silicon dioxide, or a borosilicate material.

In some embodiments, core layer 150 may include a layer including a dielectric material (hereinafter, a “dielectric layer”) 151, which may include, for example, a mold compound. The mold compound may include one or more insulating materials, such as, for example, at least one of a thermosetting resin such as an epoxy resin, a thermoplastic resin such as polyimide, or a material including the thermosetting resin and the thermoplastic resin, a glass fiber (or a glass cloth or a glass fabric, an inorganic filler, and/or a reinforcing material such as an inorganic filler, for example, a copper clad laminate (CCL), an unclad CCL, or the like). Alternatively, the mold compound may include, for example, a liquid crystal polymer (LCP). Where bonding layers are used as part of the mold compound, they may include, for example, at least one of a thermosetting resin such as an epoxy resin, a thermoplastic resin such as polyimide, or a material including the thermosetting resin and the thermoplastic resin, a glass fiber, and/or a reinforcing material such as an inorganic filler, for example, prepreg (PPG), Ajinomoto Build-up Film (ABF), and the like.

The glass sheet 156 may correspond, as suggested in FIG. 1A, to a sheet of glass that is perforated, for example through drilling, to provide through-holes therein for the provision of through-vias 166.

The core layer 150 may further include various active electronic components or passive electronic components therein. Passive electronic components could include, for example, coaxial metal inductor loops (Coax Mils), substrate-level inductor architectures. Active components may include, for example, dies embedded in the core substrate. Passive components may include, for example, resistors, capacitors, and/or inductors. The core layer 150 may further include interconnect bridges therein, either active ones or passive ones.

Core layer 150 further includes electrically conductive pathways. The electrically conductive pathways of core layer 150 correspond to electrically conductive traces and vias within the cores layer that are to conduct electrical signals within and through the core layer 150 when the microelectronic assembly 100 of FIG. 1A is in operation. The electrically conductive pathways of the core layer 150 are thus to conduct electrical signals within active (electrically active) regions of the core layer 150. The electrically conductive pathways of the core layer 150 include, for example, through-vias 166 connected to traces 162, and further, any electrically conductive pathways to and from any active or passive components of the core layer 150.

FIG. 1B shows a simplified version of glass sheet 156 of core layer 150 of FIG. 1A showing in particular an embodiment of a configuration of lateral edges of the glass sheet 156 as will be explained in further detail herein. FIG. 1B omits the depiction of any through-vias through glass sheet 156 for the sake of simplicity. The glass sheet 156 as shown in FIG. 1A corresponds to a cross section through the 3 dimensional schematic depiction of a glass sheet of FIG. 1B along a plan defined by broken lines A-A as shown in FIG. 1B.

Referring now to both FIGS. 1A and 1B, glass sheet 156 of core layer 150 is shown. At the right lateral edge and at the left lateral edge of the glass sheet, as shown in FIG. 1A, a saw street structure (SSS) 170 is shown that includes oblong SSS body 172 including a first SSS material different from the material of the glass sheet 156. Individual ones of oblong SSS bodies 172 extends vertically in a direction along a thickness of the glass sheet 156 (direction h as shown in FIG. 1A) and include the first SSS material disposed within respective oblong cavities 176 defined at lateral edges of glass sheet 156. Individual ones of the oblong SSS bodies 172 further have a lateral edge surface facing away from the sheet, that is, and SSS body 172 according to embodiments has an outer edge surface that faces outward from the sheet. In the shown embodiment of FIGS. 1A and 1B, SSS 170 further includes an top transverse SSS body 178′ and a bottom transverse SSS body 178″ including a second SSS material different from the material of the glass sheet 156. The second SSS material may be different from or the same as the first SSS material. The second SSS material of the top transverse SSS body 178′ may be different from the second SSS material of the bottom transverse SSS body 178″, or it may be the same material.

An “SSS structure” or “SSS body” as used herein refers to a structure/body that corresponds to a lateral edge region of a glass sheet of a core layer of a package substrate, the lateral edge region adjacent a saw street of a glass panel if the core layer has not yet been singulated from the glass panel, or having been adjacent to a saw street of a glass panel if the core layer has already been singulated from the glass panel.

When referring to singulation “of a core layer” (from a panel) the instant description encompasses by way of example singulation to result in “units.”

When referring to a “unit” in the context of panel-level processing, what is meant herein is a structure to result from singulation along saw streets of a panel, such as, for example, a glass sheet, a core layer including a glass sheet, a package substrate that has a core layer including a glass sheet plus one or more redistribution layers on the core layer, a microelectronic assembly (individual integrated circuit packages or “modules”) that includes a core layer including a glass sheet, one or more redistribution layers on the core layer, and one or more dies on the core layer.

The term “saw street” as used herein refers to portions of a semiconductor panel that are provided between units, and that are to be cut through during singulation/dicing. For example, a saw street may refer to portions of a semiconductor panel, such as a glass panel, where the portions define a narrow spacing between individual microelectronic assemblies on a panel, which is necessary for the cutting (or dicing) process. This spacing allows for precise cuts without damaging the functional parts of the units. The width of these saw streets may, for example be about 150-300 micrometers, such as, for example, 250 micrometers

Individual ones of the top transverse SSS body 178′ and the bottom transverse SSS body 178″ in the shown embodiment of FIGS. 1A and 1B extend in a direction transverse to a height of the oblong SSS bodies 172, and are adjacent to respective top and bottom surfaces of the oblong SSS bodies. The second SSS material is shown as being disposed within a transverse cavity defined in and extending along a top lateral edge (for the top transverse SSS body 178′) and a bottom lateral edge (for the bottom transverse SSS body 178″) of glass sheet 156.

The first SSS material and/or the second SSS material (hereinafter “the SSS material”) may include one or more polymer materials, and/or one or more metals that are relatively malleable.

A polymer material of the SSS material may be a “high” tensile strength polymer material, for example with a tensile strength range between about 15 MPa and about 55 MPa, or for example with a tensile strength between about 15 MPa to 145 MPa. The polymer material may for example include any one of PTFE (polytetrafluoroethylene), PFA (perfluoroalkoxy), PVDF (polyvinylidene fluoride), polyetherimide (PEI), polyamideimide (PAI), polyether ether ketone (PEEK), or polyvinyl fluoride (PVF). For example, the SSS material may comprise a fluorocarbon polymer (e.g., a polymer comprising fluorine and carbon).

The malleable metal may for example include one or more of Sn, Au, Ag, Pb, Al or Cu, or any other metal material (including alloys such as metal alloys) with malleability comparable to any of Sn, Au, Ag, Pb, Al or Cu.

A width of individual ones of the SSS′ 170 in the w direction as seen in FIG. 1A may for example be a fraction of a width of a saw street defined in a glass panel from which the glass sheet 156 has been singulated by dicing along said saw street. According to an embodiment, the width an SSS 170 may be based on a location of active and/or passive components in the glass sheet 156, and/or on a location of electrically conductive pathways in the glass sheet 156.

In the shown embodiment of FIG. 1A, glass sheet 156 is shown as including an SSS 170 at each lateral edge thereof. However, embodiments are not so limited. According to one embodiment, a glass sheet similar to glass sheet 156 may include one or more SSS 170 at one lateral edge thereof, at two lateral edges thereof, at three edges thereof, or at all four edges thereof.

In the shown embodiment of FIGS. 1A and 1B, SSS 170 includes an oblong SSS body 172 and two transverse SSS bodies 178′ and 178″, although embodiments are not so limited. According to some embodiments, an SSS 170 may include an oblong SSS body whose height spans from a bottom surface to a top surface of a glass sheet 156. According to some other embodiments, an SSS 170 may include the oblong SSS body 172, and only one transverse SSS body, either at the top or at the bottom thereof.

In the shown embodiment of FIG. 1B, SSS 170 is shown to include oblong SSS bodies around a perimeter of glass sheet 156 on all lateral edges thereof, although embodiments are not so limited. Some embodiments include the provision of a SSS 170 that includes oblong SSS bodies and/or transverse SSS bodies on one, two, or three lateral edges of a glass sheet 156.

In the shown embodiment of FIG. 1B, SSS 170 is shown as including a plurality of oblong SSS bodies 172 at a given lateral edge of the glass sheet, although embodiments are not so limited. Some embodiments include a SSS 170 comprising a single oblong SSS body at one lateral edge or at multiple lateral edges of the glass sheet 156, with or without transverse SSS bodies.

In the shown embodiment of FIG. 1A, the SSS 170 has a lateral edge surfaces or ends that are substantially flush with or protrude from lateral edges of the glass sheet 156 of core layer 150. That is, the glass sheet 156 of core layer 150 has a lateral edge that terminates before or at the lateral edge of the glass sheet 156 of core layer 150.

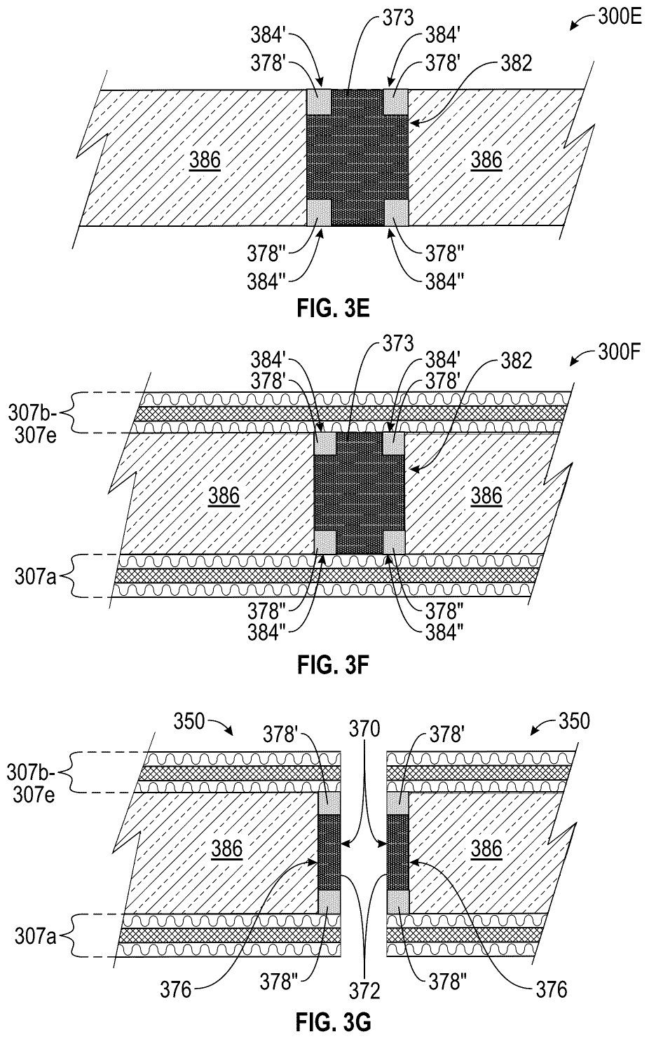

In the shown embodiment of FIG. 1A, core layer includes a single glass sheet therein, although embodiments are not so limited. According to some embodiments, core layer 150 may include a plurality of glass sheets similar to the shown glass sheet 156 adjacent to one another in the direction w as shown in FIG. 1A, with the glass sheets embedded within dielectric layer 151. According to some embodiments, one or more such glass sheets may include an SSS 170 as described with respect to the embodiments herein. The core layer 150 of FIG. 1A may, for example, be provided after a dicing of a core layer panel including a glass containing core substrate, as will be explained in further detail in relation to FIGS. 3A-3G.

Various embodiments may provide one or more advantages, such as increased protection against glass cracking during the manufacturing process, reduced manufacturing cost, improved yield, or reduced complexity in manufacturing processes.

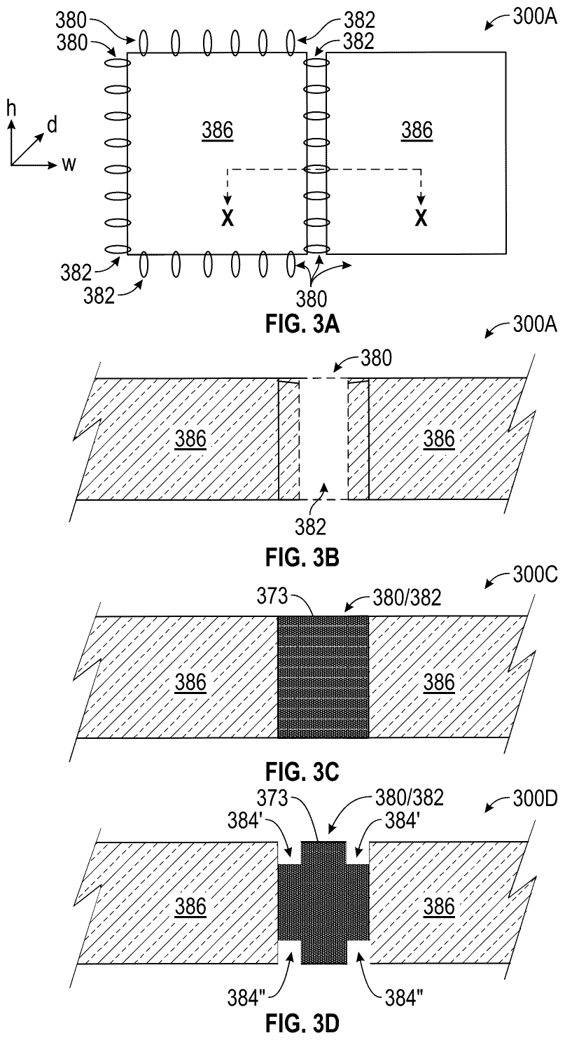

Advantageously, an SSS structure according to embodiments is to impart structural support to the glass sheet 156 of core layer during singulation of the same from a corresponding glass panel substrate. The SSS may include a material different from a material of the glass sheet 156. Preferably, the SSS material includes a material that is more ductile or malleable than a material of the glass sheet 156. More details regarding fabrication of a glass sheet similar to glass sheet 156 of core layer 150 will be provided in relation to FIGS. 2A-2C below further below.

FIGS. 2A-C illustrate an example of a glass substrate 200. In particular, perspective, plan, and cross-section views of the glass substrate 200 are shown in FIGS. 2A, 2B, and 2C, respectively. In various embodiments, the glass substrate 200 may be a glass panel, subpanel, or quarter panel including units to be singulated to generate individual glass sheets therefrom. The glass substrate 200 may include any other size or type of glass structure. For example, glass substrate 200 may correspond to a glass panel to be singulated to form individual units therefrom.

In the illustrated embodiment, the glass substrate 200 includes top and bottom surfaces/sides 202a-b and four sides/edges 204a-d.

As used herein, the term “glass,” when referring to a glass structure such as a glass substrate 200 (e.g., glass panel, subpanel, quarter panel, unit, core, substrate, etc.), may refer to one or more layers of glass (e.g., a glass sheet), a portion of a glass sheet, or other structure of any glass material. In particular, the glass may be bulk glass or a solid volume/layer of glass, as opposed to, for example, materials that may include particles of glass, such as glass fiber reinforced polymers (e.g., substrates/boards constructed of glass fibers and an epoxy binder). Such bulk/solid glass materials are typically non-crystalline, often transparent, amorphous solids. In some embodiments, the glass may be an amorphous solid glass sheet.

A glass substrate 200 may be made of, or may include, any suitable glass material, including, without limitation, quartz, silica, fused silica, silicate glass (e.g., borosilicate, aluminosilicate, alumino-borosilicate), soda-lime glass, soda-lime silica, borofloat glass, lead borate glass, photosensitive glass, non-photosensitive glass, or ceramic glass.

In some embodiments, the glass substrate 200 may be made of a material that includes elements such as silicon (Si) and oxygen (O), as well as any one or more of aluminum (Al), boron (B), magnesium (Mg), calcium (Ca), barium (Ba), tin (Sn), sodium (Na), potassium (K), strontium (Sr), phosphorus (P), zirconium (Zr), lithium (Li), titanium (Ti), or zinc (Zn).

In some embodiments, the glass substrate 200 may include a material, e.g., any of the materials described above, with a weight percentage of silicon being at least about 0.5%, e.g., between about 0.5% and 50%, between about 1% and 48%, or at least about 23%. For example, if the glass material is fused silica, the weight percentage of silicon may be about 47%. In some embodiments, the glass substrate 200 may include a material having at least 23% silicon and/or at least 26% oxygen by weight, and, in some further embodiments, the glass substrate 200 may further include at least 5% aluminum by weight.

In some embodiments, the glass substrate 200 may include any of the materials described above and may further include one or more additives, such as aluminum oxide (Al₂O₃), boron trioxide (B₂O₃), magnesium oxide (MgO), calcium oxide (CaO), strontium oxide (SrO), barium oxide (BaO), tin(IV) oxide (SnO2), sodium oxide (Na₂O), potassium oxide (K₂O), diphosphorus trioxide (P₂O₃), zirconium dioxide (ZrO₂), lithium oxide (Li₂O), titanium (Ti), and zinc (Zn).

In some embodiments, the glass substrate 200 may be a layer of glass that does not include an organic adhesive or an organic material. The glass substrate 200 may be distinguished from, for example, a “prepreg” or “RF4” core of a PCB substrate which typically includes glass fibers embedded in a resinous organic material such as an epoxy. In such traditional cores/substrates including glass fibers and epoxy, the diameter of the glass fibers is generally in the range of 5 micrometers (microns or μm) to 200 μm.

In contrast, in some embodiments, the dimensions of a glass sheet (similar to glass sheet 156 of FIGS. 1A and 1B by way of example and corresponding to a “unit”) of glass substrate 200 may be in a range of about 10 millimeters (mm) per side to 250 mm per side (e.g., 10×10 mm to 250×250 mm). Further, in some embodiments, the dimensions of the glass substrate 200 may be up to 600 mm on a side (e.g., a glass panel with dimensions of 510×515 mm or 600×600 mm).

In some embodiments, a cross-section of the glass substrate 200 in an x-z plane, y-z plane, and/or x-y plane of an example coordinate system, may be substantially rectangular. In at least some such embodiments, in a top-down or plan view of the glass substrate 200 (e.g., the x-y plane), the glass substrate 200 may comprise a solid layer of glass substantially rectangular in shape and may have a first length in a range of 10 mm to 250 mm, and a second length in a range of 10 mm to 250 mm, the first length perpendicular to the second length.

In some embodiments, the glass substrate 200 may be a layer of glass comprising a rectangular prism volume. In some such embodiments, the rectangular prism volume may have a first side and a second side perpendicular to the first side, the first side having a length in a range of 10 mm to 250 mm and the second side having a length in a range of 10 mm to 250 mm.

In some embodiments, the glass substrate 200 may have a thickness (e.g., a dimension measured along the z axis) in a range of about 50 μm to 1.4 mm. In some embodiments, for example, the glass substrate 200 may be a glass core substrate with a thickness of about 50 μm to 1.4 mm.

In some embodiments, the glass substrate 200 may be a layer of glass having a thickness in a range of 50 μm to 1.4 mm, a first length in a range of 10 mm to 250 mm, and a second length in a range of 10 mm to 250 mm, the first length perpendicular to the second length.

In some embodiments, the glass substrate 200 may be a multi-layer glass substrate (e.g., a coreless substrate), where a glass sheet of the glass substrate 200 has a thickness in a range of about 25 μm to 50 μm.

In some embodiments, the glass substrate 200 may comprise a rectangular prism volume with sections (e.g., vias) removed and filled with at least one other material (e.g., metal). For example, the glass substrate 200 may include a via extending from a first surface/side 202a,b of the rectangular prism volume to a second surface/side 202a,b of the rectangular prism volume, where the via includes a metal, thus forming a through-glass via (TGV) through the glass substrate 200, which through-vias may correspond for example to through-vias 166 of FIG. 1A.

Let us now refer to FIGS. 3A-3G which show stages of fabrication of a core layer including a glass sheet similar to glass sheet 156 of FIGS. 1A and 1B, with one distinction being that, a core layer as formed based on FIGS. 3A-2G does not include a dielectric layer (such as dielectric layer 151 of FIG. 1A) within which the glass sheet is embedded.

FIGS. 3A-3F show respective portions of glass panel structures in various stages of fabrication to result in a glass sheet according to an embodiment. FIGS. 3A-3F show respective portions of glass panel structures rather than glass panel structures in their entirety for the sake of simplicity and for ease of description herein. Processes the details of which are provided herein with respect to FIGS. 3A-3G are therefore to be understood to be applicable to a portion of a glass panel or to an entirely of a glass panel.

By “glass panel structure,” what is meant herein is a panel including glass (e.g., similar to glass substrate 200 of FIGS. 2A-2C) in any stage of fabrication prior to singulation.

In FIG. 3A, a first stage for the fabrication of a core layer according to an embodiment is shown. As seen in FIG. 3A, a top plan view is provided of a portion of a glass panel structure 300A. The shown portion includes including two glass units 386A. In FIG. 3A, saw streets 380 between units 386A, with each unit 386A corresponding to a glass sheet. As depicted in FIG. 3A, a stage of fabrication of a core layer according to some embodiments includes the provision of holes or cavities, such as blind holes (not shown), or such as through-glass holes (TGHs) 382, across a thickness of the panel structure 300A along one or more saw streets 380 of panel structure 300A. In the shown embodiment, the TGHs 382 are defined not only in the saw streets, but also through glass material of the shown units as shown. In the shown embodiment, TGHs 382 are at a periphery of one of the units 386A, and are shown as having an oval configuration in a top plan view thereof, suggesting an overall cross-sectional configuration of the TGHs 382 transverse to a direction of a height of the TGHs that is oval (as depicted by way of coordinate axes whd in FIG. 3A). An oval configuration of the cross-sectional configuration of the TGHs 382 would result in curved surfaces of cavities resulting therefrom after a singulation of the corresponding glass panel structure. However, embodiments are not so limited, and include within their scope the provision of holes in the h direction with any respective cross sectional shapes, including respective cross sectional shapes that are circular, square, rectangular, pentagonal, and/or hexagonal. The TGHs 382 may be provided using any method for providing through-holes through glass, such as by way of mechanical drilling (using drill bits, blasts, or other methods), thermal drilling (e.g., laser drilling), chemical methods (e.g., etching), or other suitable methods. The TGHs may be formed along with other TGHs of individual glass units, the other TGHs used to form through glass vias (TGVs) similar to Through-vias 166 of FIG. 1A.

In FIG. 3B is a cross sectional view of the portion of glass panel structure 300A of FIG. 3A on a plane in the hw direction along lines X-X. FIG. 3B shows the TGH 382 with an elliptical cross section across a saw street 380 of the portion of glass panel structure 380A.

In FIG. 3C, a second stage for the fabrication of a core layer according to an embodiment is shown. In FIG. 3C, a glass panel structure 300C is shown where TGHs 382 (keeping in mind FIG. 3A) are filled with first SSS material, such as any one or more of the SSS materials described above, to form through glass vias (TGVs) 372 as shown. The TGHs 382 may be filled according to some embodiments with a polymer material using one or more of liquid coating, slit coating, lamination, pressure coating. The TGHs 382 may be filled according to some embodiments with a metal material using one or more of physical vapor deposition, chemical vapor deposition, electroless plating, or screen printing to name a few.

In FIG. 3D, a third stage for the fabrication of a core layer according to an embodiment is shown. In FIG. 3D, a glass panel structure 300D is shown where grooves 384′ and 384″ are provided in the glass units and in corresponding TGVs 373 along top opposing lateral edges and along bottom opposing lateral edges of saw streets associated with the TGVs 373. Referring to FIG. 1B in conjunction with FIG. 3D: (1) the grooves 384′ are provided to correspond to top transverse SSS bodies similar to top transverse SSS body 178′ of FIG. 1B when filled with a second SSS material, and thus are defined not only through TGVs 373 but although through a material of the glass units; and (2) the grooves 384″ are provided to correspond to bottom transverse SSS bodies similar to bottom transverse SSS body 178″ of FIG. 1B when filled with a second SSS material, and thus are defined not only through TGVs 373 but although through a material of the glass units. The grooves 384′ and 384″ may be provided, according to some embodiments, by way of etching, such as wet etching, reactive ion etching, or laser ablation. The grooves may be provided, according to some embodiments, by way of mechanical drilling (using drill bits, blasts, or other methods), thermal drilling (e.g., laser drilling), chemical methods (e.g., etching), or other suitable methods.

In FIG. 3E, a fourth stage for the fabrication of a core layer according to an embodiment is shown. In FIG. 3E, a glass panel structure 300E is shown where the grooves 384′ and 384″ are shown as having been filled with the second SSS material, such as any one or more of the SSS materials described above, to form transverse SSS bodies 378′ and 378″ as shown. Where the second SSS material includes a polymer, the grooves 384′ and 384″ may be filled according to some embodiments using one or more of liquid coating, spin coating, or lamination. Where the second SSS material includes a metal, the grooves 384′ and 384″ may be filled according to some embodiments using one or more of physical vapor deposition, chemical vapor deposition, electroless plating, or screen printing to name a few. After deposition of one or more of the first SSS material or the second SSS material, some embodiments may include post filling processes (now shown) such as planarization (e.g., via chemical mechanical polishing), and/or annealing to improve adhesion and mechanical properties. In some embodiments,

In FIG. 3F, a fifth stage for the fabrication of a core layer according to an embodiment is shown. In FIG. 3F, a glass panel structure 300F is shown where buildup layers 307a-307e and 307b may be provided on top and bottom surfaces of the glass panel structure 300E of FIG. 3E. The build-up layers 307a-307e and 307b may be similar to build-up layers 107a-107e and 107b of FIG. 1A, and may be provided onto the glass panel structure 300F in the same manner. Although not shown, other package components may be formed over the glass panel structure 300F on one or more of the top and bottom surfaces thereof, such package components including, for example, dies, for example similar to dies 108 and 116 of FIG. 1A.

In FIG. 3G, a sixth stage for the fabrication of a core layer according to an embodiment is shown. In FIG. 3G, two core layers 350 are shown comparable to core layer 150 of FIGS. 1A and 1B. In this sixth stage for the fabrication of a core layer according to an embodiment, the glass panel structure 300F of FIG. 3F may be singulated in any well-known manner across saw street 380. Core layers 350 for individual units shown in FIG. 3G include glass sheet 386 which in turn includes, at the right lateral edge thereof, a saw street structure (SSS) 370 that includes oblong SSS body 372 including a first SSS material different from the material of the glass sheet 386. Individual ones of oblong SSS bodies 372 extend vertically in a direction along a thickness of the glass sheet 386 and include the first SSS material disposed within respective oblong cavities 376 defined at lateral edges of a glass sheet 386. In the shown embodiment of FIG. 3G, an SSS 370 further includes an top transverse SSS body 378′ and a bottom transverse SSS body 378″ including a second SSS material different from the material of the glass sheet 386. The second SSS material may be different from or the same as the first SSS material. The second SSS material of the top transverse SSS body 378′ may be different from the second SSS material of the bottom transverse SSS body 378″, or it may be the same material.

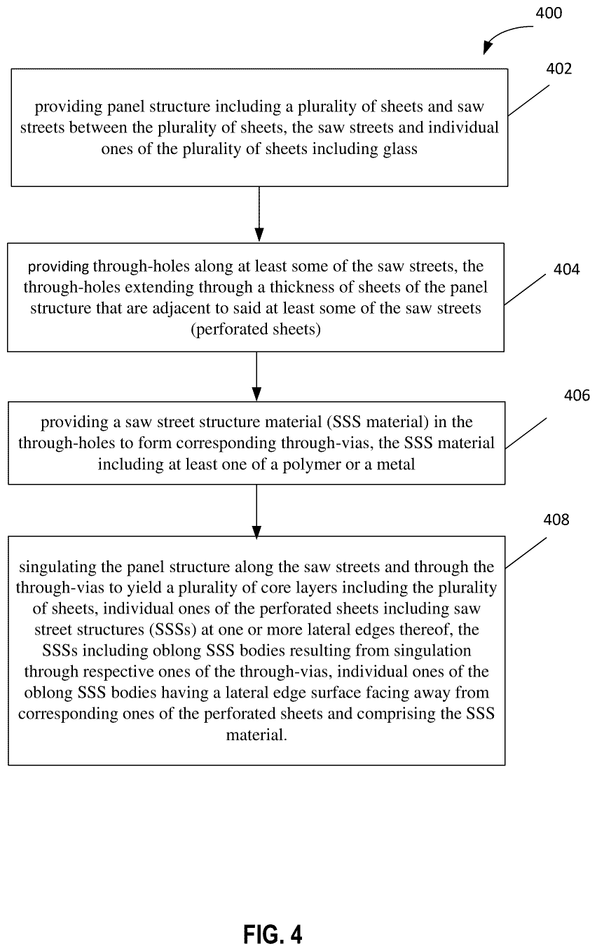

FIG. 4 is a flowchart of a process 400 according to some embodiments. At operation 402, the process includes providing panel structure including a plurality of sheets and saw streets between the plurality of sheets, the saw streets and individual ones of the plurality of sheets including glass. At operation 404, the process includes providing through-holes along at least some of the saw streets, the through-holes extending through a thickness of sheets of the panel structure that are adjacent to said at least some of the saw streets (perforated sheets). At operation 406, the process includes providing a saw street structure material (SSS material) in the through-holes to form corresponding through-vias, the SSS material including at least one of a polymer or a metal. At operation 408, the process includes singulating the panel structure along the saw streets and through the through-vias to yield a plurality of core layers including the plurality of sheets, individual ones of the perforated sheets including saw street structures (SSSs) at one or more lateral edges thereof, the SSSs including oblong SSS bodies resulting from singulation through respective ones of the through-vias, individual ones of the oblong SSS bodies having a lateral edge surface facing away from corresponding ones of the perforated sheets and comprising the SSS material.

As noted previously, various embodiments provide one or more advantages, such as increased protection against glass cracking during the manufacturing process, reduced manufacturing cost, improved yield, or reduced complexity in manufacturing processes.

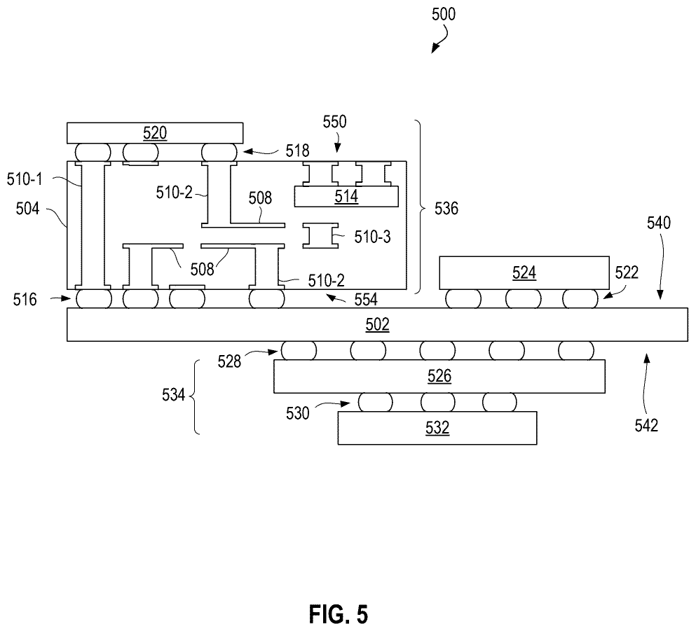

FIG. 5 is a cross-sectional side view of an integrated circuit device assembly 500 that may include one or more integrated circuit structures each including any of the microelectronic assemblies such as semiconductor packages of embodiments described herein. The integrated circuit device assembly 500 includes a number of components disposed on a circuit board 502 (which may be a motherboard, system board, mainboard, etc.). The integrated circuit device assembly 500 includes components disposed on a first face 540 of the circuit board 502 and an opposing second face 542 of the circuit board 502; generally, components may be disposed on one or both faces 540 and 542. Any of the integrated circuit components discussed below with reference to the integrated circuit device assembly 500 may include an integrated circuit structure including an interconnect structure as described herein.

In some embodiments, the circuit board 502 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 502. In other embodiments, the circuit board 502 may be a non-PCB substrate. The integrated circuit device assembly 500 illustrated in FIG. 5 includes a package-on-interposer structure 536 coupled to the first face 540 of the circuit board 502 by coupling components 516. The coupling components 516 may electrically and mechanically couple the package-on-interposer structure 536 to the circuit board 502, and may include solder balls (as shown in FIG. 5), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 536 may include an integrated circuit component 520 coupled to an interposer 504 by coupling components 518. The coupling components 518 may take any suitable form for the application, such as the forms discussed above with reference to the coupling components 516. Although a single integrated circuit component 520 is shown in FIG. 5, multiple integrated circuit components may be coupled to the interposer 504; indeed, additional interposers may be coupled to the interposer 504. The interposer 504 may provide an intervening substrate used to bridge the circuit board 502 and the integrated circuit component 520.

The integrated circuit component 520 may be a packaged or unpackaged integrated circuit product that includes one or more integrated circuit dies. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 520, a single monolithic integrated circuit die comprises solder bumps attached to contacts on the die. The solder bumps allow the die to be directly attached to the interposer 504. The integrated circuit component 520 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 520 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 520 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 520 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets.” In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 504 may spread connections to a wider pitch or reroute a connection to a different connection. For example, the interposer 504 may couple the integrated circuit component 520 to a set of ball grid array (BGA) conductive contacts of the coupling components 516 for coupling to the circuit board 502. In the embodiment illustrated in FIG. 5, the integrated circuit component 520 and the circuit board 502 are attached to opposing sides of the interposer 504; in other embodiments, the integrated circuit component 520 and the circuit board 502 may be attached to a same side of the interposer 504. In some embodiments, three or more components may be interconnected by way of the interposer 504.

In some embodiments, the interposer 504 may be formed as a PCB, including multiple metal layers separated from one another by layers of dielectric material and interconnected by electrically conductive vias. In some embodiments, the interposer 504 may be formed of an epoxy resin, a fiberglass-reinforced epoxy resin, an epoxy resin with inorganic fillers, a ceramic material, or a polymer material such as polyimide. In some embodiments, the interposer 504 may be formed of alternate rigid or flexible materials that may include the same materials described above for use in a semiconductor substrate, such as silicon, germanium, and other group III-V and group IV materials. The interposer 504 may include metal interconnects 508 and vias 510, including but not limited to through-hole vias 510-1 (that extend from a first face 550 of the interposer 504 to a second face 554 of the interposer 504), blind vias 510-2 (that extend from the first or second faces 550 or 554 of the interposer 504 to an internal metal layer), and buried vias 510-3 (that connect internal metal layers).

In some embodiments, the interposer 504 can comprise a silicon interposer. Through silicon vias (TSV) extending through the silicon interposer can connect connections on a first face of a silicon interposer to an opposing second face of the silicon interposer. In some embodiments, an interposer 504 comprising a silicon interposer can further comprise one or more routing layers to route connections on a first face of the interposer 504 to an opposing second face of the interposer 504.

The interposer 504 may further include embedded devices 514, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 504. The package-on-interposer structure 536 may take the form of any of the package-on-interposer structures known in the art. In embodiments where the interposer is a non-printed circuit board

The integrated circuit device assembly 500 may include an integrated circuit component 524 coupled to the first face 540 of the circuit board 502 by coupling components 522. The coupling components 522 may take the form of any of the embodiments discussed above with reference to the coupling components 516, and the integrated circuit component 524 may take the form of any of the embodiments discussed above with reference to the integrated circuit component 520.

The integrated circuit device assembly 500 illustrated in FIG. 5 includes a package-on-package structure 534 coupled to the second face 542 of the circuit board 502 by coupling components 528. The package-on-package structure 534 may include an integrated circuit component 526 and an integrated circuit component 532 coupled together by coupling components 530 such that the integrated circuit component 526 is disposed between the circuit board 502 and the integrated circuit component 532. The coupling components 528 and 530 may take the form of any of the embodiments of the coupling components 516 discussed above, and the integrated circuit components 526 and 532 may take the form of any of the embodiments of the integrated circuit component 520 discussed above. The package-on-package structure 534 may be configured in accordance with any of the package-on-package structures known in the art.

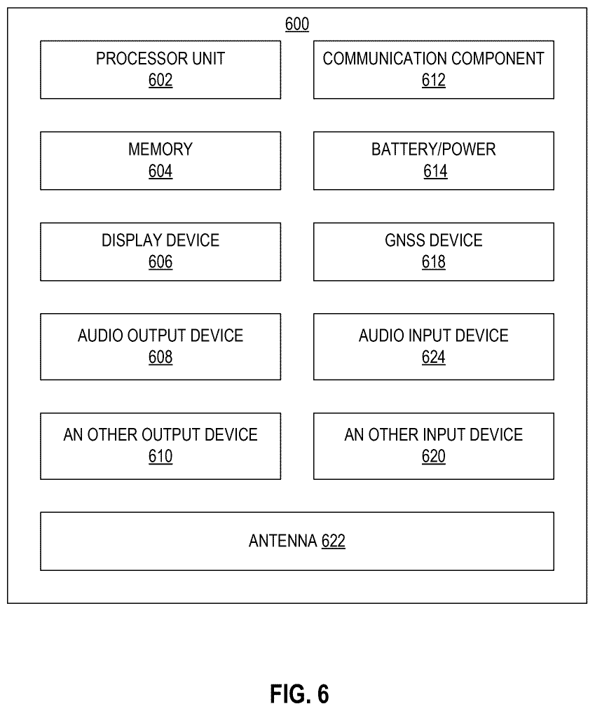

FIG. 6 is a block diagram of an example electrical device 600 that may include one or more of the embodiment semiconductor packages disclosed herein. For example, any suitable ones of the components of the electrical device 600 may include one or more of the integrated circuit device assemblies 500, integrated circuit components 520, and/or embodiment semiconductor packages disclosed herein. A number of components are illustrated in FIG. 6 as included in the electrical device 600, but any one or more of these components may be omitted or duplicated, as suitable for the application. In some embodiments, some or all of the components included in the electrical device 600 may be attached to one or more motherboards mainboards, or system boards. In some embodiments, one or more of these components are fabricated onto a single system-on-a-chip (SoC) die.

Additionally, in various embodiments, the electrical device 600 may not include one or more of the components illustrated in FIG. 6, but the electrical device 600 may include interface circuitry for coupling to the one or more components. For example, the electrical device 600 may not include a display device 606, but may include display device interface circuitry (e.g., a connector and driver circuitry) to which a display device 606 may be coupled. In another set of examples, the electrical device 600 may not include an audio input device 624 or an audio output device 608, but may include audio input or output device interface circuitry (e.g., connectors and supporting circuitry) to which an audio input device 624 or audio output device 608 may be coupled.

The electrical device 600 may include one or more processor units 602 (e.g., one or more processor units). As used herein, the terms “processor unit,” “processing unit” or “processor” may refer to any device or portion of a device that processes electronic data from registers and/or memory to transform that electronic data into other electronic data that may be stored in registers and/or memory. The processor unit 602 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 600 may include a memory 604, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 604 may include memory that is located on the same integrated circuit die as the processor unit 602. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 600 can comprise one or more processor units 602 that are heterogeneous or asymmetric to another processor unit 602 in the electrical device 600. There can be a variety of differences between the processing units 602 in a system in terms of a spectrum of metrics of merit including architectural, microarchitectural, thermal, power consumption characteristics, and the like. These differences can effectively manifest themselves as asymmetry and heterogeneity among the processor units 602 in the electrical device 600.

In some embodiments, the electrical device 600 may include a communication component 612 (e.g., one or more communication components). For example, the communication component 612 can manage wireless communications for the transfer of data to and from the electrical device 600. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 612 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 612 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 612 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 612 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 612 may operate in accordance with other wireless protocols in other embodiments. The electrical device 600 may include one or more antennas, such as antenna 622 to facilitate wireless communications and/or to receive other wireless communications (such as AM or FM radio transmissions).

In some embodiments, the communication component 612 may manage wired communications, such as electrical, optical, or any other suitable communication protocols (e.g., IEEE 802.3 Ethernet standards). As noted above, the communication component 612 may include multiple communication components. For instance, a first communication component 612 may be dedicated to shorter-range wireless communications such as Wi-Fi or Bluetooth, and a second communication component 612 may be dedicated to longer-range wireless communications such as global positioning system (GPS), EDGE, GPRS, CDMA, WiMAX, LTE, EV-DO, or others. In some embodiments, a first communication component 612 may be dedicated to wireless communications, and a second communication component 612 may be dedicated to wired communications.

The electrical device 600 may include battery/power circuitry 614. The battery/power circuitry 614 may include one or more energy storage devices (e.g., batteries or capacitors) and/or circuitry for coupling components of the electrical device 600 to an energy source separate from the electrical device 600 (e.g., AC line power).

The electrical device 600 may include a display device 606 (or corresponding interface circuitry, as discussed above). The display device 606 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 600 may include an audio output device 608 (or corresponding interface circuitry, as discussed above). The audio output device 608 may include any embedded or wired or wirelessly connected external device that generates an audible indicator, such speakers, headsets, or earbuds.

The electrical device 600 may include an audio input device 624 (or corresponding interface circuitry, as discussed above). The audio input device 624 may include any embedded or wired or wirelessly connected device that generates a signal representative of a sound, such as microphones, microphone arrays, or digital instruments (e.g., instruments having a musical instrument digital interface (MIDI) output). The electrical device 600 may include a Global Navigation Satellite System (GNSS) device 618 (or corresponding interface circuitry, as discussed above), such as a Global Positioning System (GPS) device. The GNSS device 618 may be in communication with a satellite-based system and may determine a geolocation of the electrical device 600 based on information received from one or more GNSS satellites, as known in the art.

The electrical device 600 may include another output device 610 (or corresponding interface circuitry, as discussed above). Examples of the other output device 610 may include an audio codec, a video codec, a printer, a wired or wireless transmitter for providing information to other devices, or an additional storage device.

The electrical device 600 may include another input device 620 (or corresponding interface circuitry, as discussed above). Examples of the other input device 620 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 600 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 600 may be any other electronic device that processes data. In some embodiments, the electrical device 600 may comprise multiple discrete physical components. Given the range of devices that the electrical device 600 can be manifested as in various embodiments, in some embodiments, the electrical device 600 can be referred to as a computing device or a computing system.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of embodiments has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to any single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

As used herein the terms “top,” “bottom,” “upper,” “lower,” “lowermost,” and “uppermost” when used in relationship to one or more elements are intended to convey a relative rather than absolute physical configuration. Thus, an element described as an “uppermost element” or a “top element” in a device may instead form the “lowermost element” or “bottom element” in the device when the device is inverted. Similarly, an element described as the “lowermost element” or “bottom element” in the device may instead form the “uppermost element” or “top element” in the device when the device is inverted.

As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

For the purposes of the present disclosure, the phrase “A and/or B” means (A), (B), or (A and B). For the purposes of the present disclosure, the phrase “A, B, and/or C”means (A), (B), (C), (A and B), (A and C), (B and C), or (A, B, and C).

In embodiments, the phrase “A is located on B” means that at least a part of A is in direct physical contact or indirect physical contact (having one or more other features between A and B) with at least a part of B.

In the instant description, “A is adjacent to B” means that at least part of A is in direct physical contact with at least a part of B.

In the instant description, “B is between A and C” means that at least part of B is in or along a space separating A and C and that the at least part of B is in direct or indirect physical contact with A and C.

In the instant description, “A is attached to B” means that at least part of A is mechanically attached to at least part of B, either directly or indirectly (having one or more other features between A and B).

In the instant description, “the As are coupled to the Bs” means that at least some of the As are coupled to at least some of the Bs, and not necessarily that all As are coupled to at least one B and all Bs are coupled to at least one A.

In the instant description, “A is within B” means that at least some of A is encompassed within the physical boundaries of B.

The use of reference numerals separated by a “/”, such as “102/104” for example, is intended to refer to 102 or 104 as appropriate. Otherwise, the forward slash (“/”) as used herein means “and/or.”When used to describe a range of dimensions, the phrase “between X and Y” represents a range that includes X and Y. Although certain elements may be referred to in the singular herein, such elements may include multiple sub-elements. For example, “an insulating material” may include one or more insulating materials. As used herein, a “conductive contact” may refer to a portion of conductive material (e.g., metal) serving as an electrical interface between different components; conductive contacts may be recessed in, flush with, or extending away from a surface of a component, and may take any suitable form (e.g., a conductive pad or socket, or portion of a conductive line or via).

The use of the techniques and structures provided herein can be detected using tools such as: electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. In particular, such tools can indicate an integrated circuit including at least one semiconductor package including an embedded magnetic inductor.

In some embodiments, the techniques, processes and/or methods described herein can be detected based on the structures formed therefrom. In addition, in some embodiments, the techniques and structures described herein can be detected based on the benefits derived therefrom. Numerous configurations and variations will be apparent in light of this disclosure.

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” “according to some embodiments,” “in accordance with embodiments,” or “in embodiments,” which may each refer to one or more of the same or different embodiments. Furthermore, the terms “comprising,” “including,” “having,” and the like, as used with respect to embodiments of the present disclosure, are synonymous.

“Coupled” as used herein means that two or more elements are in direct physical contact, or that that two or more elements indirectly physically contact each other, but yet still cooperate or interact with each other (i.e., one or more other elements are coupled or connected between the elements that are said to be coupled with each other). The term “directly coupled”means that two or more elements are in direct contact.

As used herein, the term “module” refers to being part of, or including an ASIC, an electronic circuit, a system on a chip, a processor (shared, dedicated, or group), a solid state device, a memory (shared, dedicated, or group) that execute one or more software or firmware programs, a combinational logic circuit, and/or other suitable components that provide the described functionality.

As used herein, “electrically conductive” in some examples may refer to a property of a material having an electrical conductivity greater than or equal to 10⁷ Siemens per meter (S/m) at 20 degrees Celsius. Examples of such materials include Cu, Ag, Al, Au, W, Zn and Ni.

In the corresponding drawings of the embodiments, signals, currents, electrical biases, or magnetic or electrical polarities may be represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, polarity, current, voltage, etc., as dictated by design needs or preferences, may actually comprise one or more signals that may travel in either direction and may be implemented with any suitable type of signal scheme.

Throughout the specification, and in the claims, the terms “coupled” or “connected” mean a direct or indirect connection, such as a direct electrical, mechanical, or magnetic connection between the elements that are connected or an indirect connection, through one or more passive or active intermediary devices. The term “signal” may refer to at least one current signal, voltage signal, magnetic signal, or data/clock signal. The meaning of “a,” “an,” and “the” include plural references. The meaning of “in” includes “in” and “on.”

The terms “substantially,” “close,” “approximately,” “near,” and “about,” generally refer to being within +/-10% of a target value (unless specifically specified). Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner, and are not intended to imply that the objects so described must necessarily be made of different materials or have different dimensions.

For purposes of the embodiments, any transistors in various circuits and logic blocks described here are metal oxide semiconductor (MOS) transistors or their derivatives, where the MOS transistors include drain, source, gate, and bulk terminals. The transistors and/or the MOS transistor derivatives also include Tri-Gate and FinFET transistors, Gate All Around Cylindrical Transistors, Tunneling FET (TFET), Square Wire, or Rectangular Ribbon Transistors, ferroelectric FET (FeFETs), or other devices implementing transistor functionality like carbon nanotubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors—BJT PNP/NPN, BiCMOS, CMOS, eFET, etc., may be used without departing from the scope of the disclosure. The term “MN” indicates an n-type transistor (e.g., nMOS, NPN BJT, etc.) and the term “MP” indicates a p-type transistor (e.g., pMOS, PNP BJT, etc.).

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

### Examples

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.
Examples 1 includes a core layer of a package substrate, the core layer including: a sheet including glass; structures defining electrically conductive pathways within the sheet; and a saw street structure (SSS) at one or more lateral edges of the sheet, the SSS one or more oblong bodies in respective cavities defined in one or more lateral edges of the sheet, individual ones of the one or more oblong bodies extending in a direction along a thickness of the sheet, having a lateral edge surface facing away from the sheet, and comprising a material (SSS material) including at least one of a polymer or a metal.
Example 2 includes the subject matter of Example 1, wherein the one or more oblong SSS bodies extends from a top surface to a bottom surface of the sheet.
Example 3 includes the subject matter of any one of Examples 1-2, wherein the sheet includes a curved surface defining the respective cavities.
Example 4 includes the subject matter of any one of Examples 1-3, wherein the lateral edge surface of said individual ones of the one or more oblong SSS bodies is one of flush with a corresponding lateral surface of the sheet or protrudes from the corresponding lateral surface of the sheet.
Example 5 includes the subject matter of any one of Examples 1-4, the SSS material being a first SSS material and the respective cavities being first cavities; the SSS further including one or more transverse SSS bodies in respective second cavities defined in the sheet and extending in a direction transverse to a direction of the thickness of the sheet, wherein individual ones of the one or more transverse SSS bodies: are one of adjacent to a top surface of at least some of the one or more oblong SSS bodies or adjacent to a bottom surface of at least some of the one or more oblong SSS bodies; and include a second SSS material including at least one of a polymer or a metal.
Example 6 includes the subject matter of Example 5, wherein: the SSS is at all lateral edges of the sheet; the one or more oblong SSS bodies include a plurality of oblong SSS bodies in respective first cavities at a periphery of the sheet; the one or more transverse SSS bodies include: a top transverse SSS body around a periphery of a top surface of the sheet, having a top surface facing away from the sheet, and adjacent to a top surface of the plurality of oblong SSS bodies; and a bottom transverse SSS body around a periphery of a bottom surface of the sheet, having a bottom surface facing away from the sheet, and adjacent to a bottom surface of the plurality of oblong SSS bodies.
Example 7 includes the subject matter of any one of Examples 5-6, wherein, the first SSS material includes a first polymer, the second SSS material includes a second polymer different from the first polymer, and the SSS includes an interfacial layer between the first SSS material and the second SSS material, the interfacial layer including both elements from the first SSS material and elements from the second SSS material
Example 8 includes the subject matter of any one of Examples 5-6, wherein the first SSS material and the second SSS material correspond to a same material.
Example 9 includes the subject matter of any one of Examples 1-8, wherein the polymer includes carbon and fluorine.
Example 10 includes the subject matter of any one of Examples 1-8, wherein the polymer includes at least one of polytetrafluoroethylene (PTFE), perfluoroalkoxy (PFA), polyvinylidene fluoride (PVDF), polyetherimide (PEI), polyamideimide (PAI), polyether ether ketone (PEEK), or polyvinyl fluoride (PVF).
Example 11 includes the subject matter of any one of Examples 1-8, wherein the metal includes at least one of Sn, Au, Ag, Pb, Al or Cu.
Example 12 includes the subject matter of any one of Examples 1-11, wherein the glass includes silicon, and at least one of oxygen or boron.
Example 13 includes the subject matter of any one of Examples 1-12, further including a dielectric layer, the sheet embedded within the dielectric layer.
Example 14 includes the subject matter of Example 13, wherein the sheet including glass is a first sheet including glass, the structures defining electrically conductive structures are first structures defining electrically conductive structures, the SSS is a first SSS, the one or more oblong SSS bodies are one or more first oblong SSS bodies, the core layer further including: a second sheet including glass and embedded in the dielectric layer; second structures defining electrically conductive pathways within the second sheet; and a second SSS at one or more lateral edges of the second sheet, the second SSS including one or more second oblong SSS bodies in respective cavities defined in the second sheet, individual ones of The one or more second oblong SSS bodies extending in a direction along a thickness of the second sheet, having a lateral edge surface facing away from the second sheet, and comprising an SSS material including at least one of a polymer or a metal.
Examples 15 includes a package substrate including: a core layer comprising: a sheet including glass; structures defining electrically conductive pathways within the sheet; and a saw street structure (SSS) at one or more lateral edges of the sheet, the SSS one or more oblong bodies in respective cavities defined in one or more lateral edges of the sheet, individual ones of the one or more oblong bodies extending in a direction along a thickness of the sheet, having a lateral edge surface facing away from the sheet, and comprising a material (SSS material) including at least one of a polymer or a metal; and a plurality of build-up layers on at least one of a top surface or a bottom surface of the core layer, the plurality of build-up layers electrically coupled to the electrically conductive pathways of the core layer.
Example 16 includes the subject matter of Example 15, wherein the one or more oblong SSS bodies extends from a top surface to a bottom surface of the sheet.
Example 17 includes the subject matter of any one of Examples 15-16, wherein the sheet includes a curved surface defining the respective cavities.
Example 18 includes the subject matter of any one of Examples 15-17, wherein the lateral edge surface of said individual ones of the one or more oblong SSS bodies is one of flush with a corresponding lateral surface of the sheet or protrudes from the corresponding lateral surface of the sheet.
Example 19 includes the subject matter of any one of Examples 15-18, the SSS material being a first SSS material and the respective cavities being first cavities; the SSS further including one or more transverse SSS bodies in respective second cavities defined in the sheet and extending in a direction transverse to a direction of the thickness of the sheet, wherein individual ones of the one or more transverse SSS bodies: are one of adjacent to a top surface of at least some of the one or more oblong SSS bodies or adjacent to a bottom surface of at least some of the one or more oblong SSS bodies; and include a second SSS material including at least one of a polymer or a metal.
Example 20 includes the subject matter of Example 19, wherein: the SSS is at all lateral edges of the sheet; the one or more oblong SSS bodies include a plurality of oblong SSS bodies in respective first cavities at a periphery of the sheet; the one or more transverse SSS bodies include: a top transverse SSS body around a periphery of a top surface of the sheet, having a top surface facing away from the sheet, and adjacent to a top surface of the plurality of oblong SSS bodies; and a bottom transverse SSS body around a periphery of a bottom surface of the sheet, having a bottom surface facing away from the sheet, and adjacent to a bottom surface of the plurality of oblong SSS bodies.
Example 21 includes the subject matter of any one of Examples 19-20, wherein, the first SSS material includes a first polymer, the second SSS material includes a second polymer different from the first polymer, and the SSS includes an interfacial layer between the first SSS material and the second SSS material, the interfacial layer including both elements from the first SSS material and elements from the second SSS material
Example 22 includes the subject matter of any one of Examples 19-20, wherein the first SSS material and the second SSS material correspond to a same material.
Example 23 includes the subject matter of any one of Examples 15-22, wherein the polymer includes carbon and fluorine.
Example 24 includes the subject matter of any one of Examples 15-22, wherein the polymer includes at least one of polytetrafluoroethylene (PTFE), perfluoroalkoxy (PFA), polyvinylidene fluoride (PVDF), polyetherimide (PEI), polyamideimide (PAI), polyether ether ketone (PEEK), or polyvinyl fluoride (PVF).
Example 25 includes the subject matter of any one of Examples 15-22, wherein the metal includes at least one of Sn, Au, Ag, Pb, Al or Cu.
Example 26 includes the subject matter of any one of Examples 15-25, wherein the glass includes silicon, and at least one of oxygen or boron.
Example 27 includes the subject matter of any one of Examples 15-26, further including a dielectric layer, the sheet embedded within the dielectric layer.
Example 28 includes the subject matter of Example 27, wherein the sheet including glass is a first sheet including glass, the structures defining electrically conductive structures are first structures defining electrically conductive structures, the SSS is a first SSS, the one or more oblong SSS bodies are one or more first oblong SSS bodies, the core layer further including: a second sheet including glass and embedded in the dielectric layer; second structures defining electrically conductive pathways within the second sheet; and a second SSS at one or more lateral edges of the second sheet, the second SSS including one or more second oblong SSS bodies in respective cavities defined in the second sheet, individual ones of The one or more second oblong SSS bodies extending in a direction along a thickness of the second sheet, having a lateral edge surface facing away from the second sheet, and comprising an SSS material including at least one of a polymer or a metal.
Example 29 includes a microelectronic assembly including: a package substrate including: a core layer comprising: a sheet including glass; structures defining electrically conductive pathways within the sheet; and a saw street structure (SSS) at one or more lateral edges of the sheet, the SSS one or more oblong bodies in respective cavities defined in one or more lateral edges of the sheet, individual ones of the one or more oblong bodies extending in a direction along a thickness of the sheet, having a lateral edge surface facing away from the sheet, and comprising a material (SSS material) including at least one of a polymer or a metal; and a plurality of build-up layers on at least one of a top surface or a bottom surface of the core layer, the plurality of build-up layers electrically coupled to the electrically conductive pathways of the core layer; and a plurality of dies on the package substrate and electrically coupled to the electrically conductive pathways of the core layer.
Example 30 includes the subject matter of Example 29, wherein the one or more oblong SSS bodies extends from a top surface to a bottom surface of the sheet.
Example 31 includes the subject matter of any one of Examples 29-30, wherein the sheet includes a curved surface defining the respective cavities.
Example 32 includes the subject matter of any one of Examples 29-31, wherein the lateral edge surface of said individual ones of the one or more oblong SSS bodies is one of flush with a corresponding lateral surface of the sheet or protrudes from the corresponding lateral surface of the sheet.
Example 33 includes the subject matter of any one of Examples 29-32, the SSS material being a first SSS material and the respective cavities being first cavities; the SSS further including one or more transverse SSS bodies in respective second cavities defined in the sheet and extending in a direction transverse to a direction of the thickness of the sheet, wherein individual ones of the one or more transverse SSS bodies: are one of adjacent to a top surface of at least some of the one or more oblong SSS bodies or adjacent to a bottom surface of at least some of the one or more oblong SSS bodies; and include a second SSS material including at least one of a polymer or a metal.
Example 34 includes the subject matter of Example 33, wherein: the SSS is at all lateral edges of the sheet; the one or more oblong SSS bodies include a plurality of oblong SSS bodies in respective first cavities at a periphery of the sheet; the one or more transverse SSS bodies include: a top transverse SSS body around a periphery of a top surface of the sheet, having a top surface facing away from the sheet, and adjacent to a top surface of the plurality of oblong SSS bodies; and a bottom transverse SSS body around a periphery of a bottom surface of the sheet, having a bottom surface facing away from the sheet, and adjacent to a bottom surface of the plurality of oblong SSS bodies.
Example 35 includes the subject matter of any one of Examples 33-34, wherein, the first SSS material includes a first polymer, the second SSS material includes a second polymer different from the first polymer, and the SSS includes an interfacial layer between the first SSS material and the second SSS material, the interfacial layer including both elements from the first SSS material and elements from the second SSS material
Example 36 includes the subject matter of any one of Examples 33-34, wherein the first SSS material and the second SSS material correspond to a same material.
Example 37 includes the subject matter of any one of Examples 29-36, wherein the polymer includes carbon and fluorine.
Example 38 includes the subject matter of any one of Examples 29-36, wherein the polymer includes at least one of polytetrafluoroethylene (PTFE), perfluoroalkoxy (PFA), polyvinylidene fluoride (PVDF), polyetherimide (PEI), polyamideimide (PAI), polyether ether ketone (PEEK), or polyvinyl fluoride (PVF).
Example 39 includes the subject matter of any one of Examples 29-36, wherein the metal includes at least one of Sn, Au, Ag, Pb, Al or Cu.
Example 40 includes the subject matter of any one of Examples 29-39, wherein the glass includes silicon, and at least one of oxygen or boron.
Example 41 includes the subject matter of any one of Examples 29-40, further including a dielectric layer, the sheet embedded within the dielectric layer.
Example 42 includes the subject matter of Example 41, wherein the sheet including glass is a first sheet including glass, the structures defining electrically conductive structures are first structures defining electrically conductive structures, the SSS is a first SSS, the one or more oblong SSS bodies are one or more first oblong SSS bodies, the core layer further including: a second sheet including glass and embedded in the dielectric layer; second structures defining electrically conductive pathways within the second sheet; and a second SSS at one or more lateral edges of the second sheet, the second SSS including one or more second oblong SSS bodies in respective cavities defined in the second sheet, individual ones of The one or more second oblong SSS bodies extending in a direction along a thickness of the second sheet, having a lateral edge surface facing away from the second sheet, and comprising an SSS material including at least one of a polymer or a metal.
Examples 43 includes a method of fabricating core layers of microelectronic package substrates, the method including: providing panel structure including a plurality of sheets and saw streets between the plurality of sheets, the saw streets and individual ones of the plurality of sheets including glass; providing through-holes along at least some of the saw streets, the through-holes extending through a thickness of sheets of the panel structure that are adjacent to said at least some of the saw streets (perforated sheets); providing a saw street structure material (SSS material) in the through-holes to form corresponding through-vias, the SSS material including at least one of a polymer or a metal; and singulating the panel structure along the saw streets and through the through-vias to yield a plurality of core layers including the plurality of sheets, individual ones of the perforated sheets including saw street structures (SSSs) at one or more lateral edges thereof, the SSSs including oblong SSS bodies resulting from singulation through respective ones of the through-vias, individual ones of the oblong SSS bodies having a lateral edge surface facing away from corresponding ones of the perforated sheets and comprising the SSS material.
Example 44 includes the subject matter of Example 43, wherein individual ones of the oblong SSS bodies extends from a top surface to a bottom surface of an associated one of the sheets with through vias.
Example 45 includes the subject matter of any one of Examples 43-44, wherein the through-holes have an elliptical transverse cross section.
Example 46 includes the subject matter of any one of Examples 43-45, wherein the lateral edge surface of said individual ones of the oblong SSS bodies is one of flush with a corresponding lateral surface of an associated one of the sheets with through vias, or protrudes from the corresponding lateral surface of the associated one of the sheets with through vias.
Example 47 includes the subject matter of any one of Examples 43-46, the SSS material being a first SSS material, the method further including: providing grooves in respective ones of the perforated sheets prior to singulating, the grooves extending in a direction transverse to a direction of a height of the through-holes; and providing a second SSS material in the grooves to form transverse SSS bodies, wherein the second SSS material includes a polymer or a metal, and wherein individual ones of the transverse SSS bodies, after singulation, are one of adjacent to a top surface of the oblong SSS bodies or adjacent to a bottom surface of the oblong SSS bodies.
Example 48 includes the subject matter of Example 47, wherein: individual ones of the SSSs are at all lateral edges of corresponding ones of the perforated sheets; the oblong SSS bodies are in respective first cavities at a periphery of individual ones of the perforated sheets; the transverse SSS bodies include, for individual ones of the perforated sheets: a top transverse SSS body around a periphery of a top surface of said individual ones of the perforated sheets, the top transverse SSS body having a top surface facing away from said individual ones of the perforated sheets, and adjacent to a top surface of the oblong SSS bodies; and a bottom transverse SSS body around a periphery of a bottom surface of said individual ones of the perforated sheets, the bottom transverse SSS body having a bottom surface facing away from said individual ones of the perforated sheets, and adjacent to a bottom surface of the oblong SSS bodies.
Example 49 includes the subject matter of any one of Examples 47-48, wherein, the first SSS material includes a first polymer, the second SSS material includes a second polymer different from the first polymer, and individual ones of the SSSs include an interfacial layer between the first SSS material and the second SSS material, the interfacial layer including both elements from the first SSS material and elements from the second SSS material
Example 50 includes the subject matter of any one of Examples 47-48, wherein the first SSS material and the second SSS material correspond to a same material.
Example 51 includes the subject matter of any one of Examples 43-50, wherein the polymer includes carbon and fluorine.
Example 52 includes the subject matter of any one of Examples 43-50, wherein the polymer includes at least one of polytetrafluoroethylene (PTFE), perfluoroalkoxy (PFA), polyvinylidene fluoride (PVDF), polyetherimide (PEI), polyamideimide (PAI), polyether ether ketone (PEEK), or polyvinyl fluoride (PVF).
Example 53 includes the subject matter of any one of Examples 43-50, wherein the metal includes at least one of Sn, Au, Ag, Pb, Al or Cu.
Example 54 includes the subject matter of any one of Examples 43-53, wherein the glass includes silicon, and at least one of oxygen or boron.
Example 55 includes the subject matter of any one of Examples 43-54, further including after singulating, embedding a plurality of the perforated sheets in respective dielectric layers to form the core layers.

What is claimed is:

1. A core layer of a package substrate, the core layer including:
a sheet including glass;
structures defining electrically conductive pathways within the sheet; and
a saw street structure (SSS) at one or more lateral edges of the sheet, the SSS one or more oblong bodies in respective cavities defined in one or more lateral edges of the sheet, individual ones of the one or more oblong bodies extending in a direction along a thickness of the sheet, having a lateral edge surface facing away from the sheet, and comprising a material (SSS material) including at least one of a polymer or a metal.

2. The core layer of claim 1, wherein the lateral edge surface of said individual ones of the one or more oblong SSS bodies is one of flush with a corresponding lateral surface of the sheet or protrudes from the corresponding lateral surface of the sheet.

3. The core layer of claim 1, the SSS material being a first SSS material and the respective cavities being first cavities; the SSS further including one or more transverse SSS bodies in respective second cavities defined in the sheet and extending in a direction transverse to a direction of the thickness of the sheet, wherein individual ones of the one or more transverse SSS bodies:
are one of adjacent to a top surface of at least some of the one or more oblong SSS bodies or adjacent to a bottom surface of at least some of the one or more oblong SSS bodies; and
include a second SSS material including at least one of a polymer or a metal.

4. The core layer of claim 3, wherein:
the SSS is at all lateral edges of the sheet;
the one or more oblong SSS bodies include a plurality of oblong SSS bodies in respective first cavities at a periphery of the sheet; and
the one or more transverse SSS bodies include:
a top transverse SSS body around a periphery of a top surface of the sheet, having a top surface facing away from the sheet, and adjacent to a top surface of the plurality of oblong SSS bodies; and
a bottom transverse SSS body around a periphery of a bottom surface of the sheet, having a bottom surface facing away from the sheet, and adjacent to a bottom surface of the plurality of oblong SSS bodies.

5. The core layer of claim 3, wherein, the first SSS material includes a first polymer, the second SSS material includes a second polymer different from the first polymer, and the SSS includes an interfacial layer between the first SSS material and the second SSS material, the interfacial layer including both elements from the first SSS material and elements from the second SSS material.

6. The core layer of claim 3, wherein the first SSS material and the second SSS material correspond to a same material.

7. The core layer of claim 1, wherein the polymer includes carbon and fluorine.

8. The core layer of claim 1, wherein the metal includes at least one of Sn, Au, Ag, Pb, Al or Cu.

9. The core layer of claim 1, wherein the sheet including glass is a first sheet including glass, the structures defining electrically conductive structures are first structures defining electrically conductive structures, the SSS is a first SSS, the one or more oblong SSS bodies are one or more first oblong SSS bodies, the core layer further including:
a second sheet including glass;
second structures defining electrically conductive pathways within the second sheet; and
a second SSS at one or more lateral edges of the second sheet, the second SSS including one or more second oblong SSS bodies in respective cavities defined in the second sheet, individual ones of the one or more second oblong SSS bodies extending in a direction along a thickness of the second sheet, having a lateral edge surface facing away from the second sheet, and comprising an SSS material including at least one of a polymer or a metal.

10. A package substrate including:
a core layer comprising:
a sheet including glass;
structures defining electrically conductive pathways within the sheet; and
a saw street structure (SSS) at one or more lateral edges of the sheet, the SSS including one or more oblong bodies in respective cavities defined in one or more lateral edges of the sheet, individual ones of the one or more oblong bodies extending in a direction along a thickness of the sheet, having a lateral edge surface facing away from the sheet, and comprising a material (SSS material) including at least one of a polymer or a metal; and
a plurality of build-up layers on at least one of a top surface or a bottom surface of the core layer, the plurality of build-up layers electrically coupled to the electrically conductive pathways of the core layer.

11. The package substrate of claim 10, wherein the lateral edge surface of said individual ones of the one or more oblong SSS bodies is one of flush with a corresponding lateral surface of the sheet or protrudes from the corresponding lateral surface of the sheet.

12. The package substrate of claim 10, the SSS material being a first SSS material and the respective cavities being first cavities; the SSS further including one or more transverse SSS bodies in respective second cavities defined in the sheet and extending in a direction transverse to a direction of the thickness of the sheet, wherein individual ones of the one or more transverse SSS bodies:
are one of adjacent to a top surface of at least some of the one or more oblong SSS bodies or adjacent to a bottom surface of at least some of the one or more oblong SSS bodies; and
include a second SSS material including at least one of a polymer or a metal.

13. The package substrate of claim 12, wherein, the first SSS material includes a first polymer, the second SSS material includes a second polymer different from the first polymer, and the SSS includes an interfacial layer between the first SSS material and the second SSS material, the interfacial layer including both elements from the first SSS material and elements from the second SSS material.

14. The package substrate of claim 10, wherein the lateral edge surface of said individual ones of the one or more oblong SSS bodies is one of flush with a corresponding lateral surface of the sheet or protrudes from the corresponding lateral surface of the sheet.

15. The package substrate of claim 10, the SSS material being a first SSS material and the respective cavities being first cavities; the SSS further including one or more transverse SSS bodies in respective second cavities defined in the sheet and extending in a direction transverse to a direction of the thickness of the sheet, wherein individual ones of the one or more transverse SSS bodies: are one of adjacent to a top surface of at least some of the one or more oblong SSS bodies or adjacent to a bottom surface of at least some of the one or more oblong SSS bodies; and include a second SSS material including at least one of a polymer or a metal.

16. The package substrate of claim 15, wherein the SSS is at all lateral edges of the sheet; the one or more oblong SSS bodies include a plurality of oblong SSS bodies in respective first cavities at a periphery of the sheet; the one or more transverse SSS bodies include: a top transverse SSS body around a periphery of a top surface of the sheet, having a top surface facing away from the sheet, and adjacent to a top surface of the plurality of oblong SSS bodies; and a bottom transverse SSS body around a periphery of a bottom surface of the sheet, having a bottom surface facing away from the sheet, and adjacent to a bottom surface of the plurality of oblong SSS bodies.

17. A method of fabricating core layers of microelectronic package substrates, the method including:
providing panel structure including a plurality of sheets and saw streets between the plurality of sheets, the saw streets and individual ones of the plurality of sheets including glass;
providing through-holes along at least some of the saw streets, the through-holes extending through a thickness of sheets of the panel structure that are adjacent to said at least some of the saw streets (perforated sheets);
providing a saw street structure material (SSS material) in the through-holes to form corresponding through-vias, the SSS material including at least one of a polymer or a metal; and
singulating the panel structure along the saw streets and through the through-vias to yield a plurality of core layers including the plurality of sheets, individual ones of the perforated sheets including saw street structures (SSSs) at one or more lateral edges thereof, the SSSs including oblong SSS bodies resulting from singulation through respective ones of the through-vias, individual ones of the oblong SSS bodies having a lateral edge surface facing away from corresponding ones of the perforated sheets and comprising the SSS material.

18. The method of claim 17, wherein the lateral edge surface of said individual ones of the oblong SSS bodies is one of flush with a corresponding lateral surface of an associated one of the sheets with through vias, or protrudes from the corresponding lateral surface of the associated one of the sheets with through vias.

19. The method of claim 17, the SSS material being a first SSS material, the method further including:
providing grooves in respective ones of the perforated sheets prior to singulating, the grooves extending in a direction transverse to a direction of a height of the through-holes; and
providing a second SSS material in the grooves to form transverse SSS bodies, wherein the second SSS material includes a polymer or a metal, and wherein individual ones of the transverse SSS bodies, after singulation, are one of adjacent to a top surface of the oblong SSS bodies or adjacent to a bottom surface of the oblong SSS bodies.

20. The method of claim 19, wherein:
individual ones of the SSSs are at all lateral edges of corresponding ones of the perforated sheets;
the oblong SSS bodies are in respective first cavities at a periphery of individual ones of the perforated sheets; and
the transverse SSS bodies include, for individual ones of the perforated sheets:
a top transverse SSS body around a periphery of a top surface of said individual ones of the perforated sheets, the top transverse SSS body having a top surface facing away from said individual ones of the perforated sheets, and adjacent to a top surface of the oblong SSS bodies; and
a bottom transverse SSS body around a periphery of a bottom surface of said individual ones of the perforated sheets, the bottom transverse SSS body having a bottom surface facing away from said individual ones of the perforated sheets, and adjacent to a bottom surface of the oblong SSS bodies.
